(19) United States
(12) Patent Application Publication
(10) Pub. No.: US 2026/0290444 A1
(43) Pub. Date: Sep. 24, 2026

(54) Memory Power Rail Ramp-Up Control

(71) Applicant: QUALCOMM Incorporated, San Diego, CA (US)

(72) Inventors: Senpeng SHENG, Chandler, AZ (US); Sunghyun PARK, Campbell, CA (US)

(21) Appl. No.: 19/084,521

(22) Filed: Mar. 19, 2025

(51) Int. Cl. G11C 11/417; G11C 5/14

(52) U.S. Cl. CPC G11C 11/417; G11C 5/145; G11C 5/147

(57) ABSTRACT

An integrated circuit is disclosed having a core power supply voltage rail supporting a core power supply voltage regulated by a core power supply voltage regulator. The integrated circuit also includes an always-on power supply voltage rail supporting an always-on power supply voltage regulated by an always-on power supply voltage regulator. A memory power supply voltage rail couples to an input power node of a memory in the integrated circuit to provide a memory power supply voltage to the memory. A multiplexer selectively couples the memory power supply voltage rail to either the always-on power supply voltage rail or to the core power supply voltage rail depending upon the operating mode of the memory.

### TECHNICAL FIELD

This application relates to memories, and more particularly to memories with power rail ramp-up control.

### BACKGROUND

To increase operating flexibility and reduce power consumption, an integrated circuit with an embedded memory such as a static random-access memory (SRAM) may be divided into separate power domains. A core power supply voltage (VDDCX) powers a core domain including a processor whereas a memory domain (MX) including the SRAM is powered by an memory power supply voltage (VDDMX). The memory domain will typically have various operating modes in which the memory power supply voltage is varied according to the memory operating mode including a sleep mode in which the memory domain is powered down. Analogous to the memory domain, the core domain may also be placed into various operating modes in which the core power supply voltage is varied including a sleep mode in which the core domain is powered down. In addition, the integrated circuit may include an always-on (AON) power domain powered by an AON power supply voltage. As implied by its name, the AON power domain is not powered down during operation such that the AON power supply voltage is maintained at a constant AON level.

In accordance with an aspect of the disclosure, an integrated circuit is provided that includes: a core power supply voltage regulator configured to regulate a core power supply voltage coupled onto a core power supply voltage rail; an always-on power supply voltage regulator configured to regulate an always-on power supply voltage coupled onto an always-on power supply voltage rail; a memory including an input power node to receive an internal power supply voltage; and a multiplexer including a first transistor and a second transistor coupled in parallel between the always-on power supply voltage rail and the input power node and including at least a third transistor coupled between the core power supply voltage rail and the input power node, wherein the first transistor is larger than the second transistor.

In accordance with another aspect of the disclosure, a method of powering an integrated circuit is provided that includes: switching on a first transistor coupled between an always-on power supply voltage rail and a memory power supply voltage rail for a memory of the integrated circuit while a second transistor coupled between the always-on power supply voltage rail and the memory power supply voltage rail is maintained off to cause a memory power supply voltage carried by the memory power supply voltage rail to increase from ground towards an active level equaling an always-on power supply voltage during a first transition period from a sleep mode for the memory to an active mode for the memory; and switching on the first transistor simultaneously with the second transistor to cause the memory power supply voltage to increase from a retention level to the active level during a second transition period from a retention mode for the memory to the active mode, wherein the first transition period is longer than the second transition period, and the retention level is less than the active level.

Finally, in accordance with yet another aspect of the disclosure, a system is provided that includes: a memory power supply voltage rail; a memory configured to be powered by a memory power supply voltage from the memory power supply voltage rail; an always-on power supply voltage rail; an always-on power domain configured to be powered by an always-on power supply voltage from the always-on power supply voltage rail; and first means for coupling the always-on power supply voltage rail to the memory power supply voltage rail to cause the memory power supply voltage to increase at a first rate during a transition of the memory from a sleep mode in which the memory is powered down to an active mode in which the memory power supply voltage equals the always-on power supply voltage and to cause the memory power supply voltage to increase at a second rate during a transition of the memory from a retention mode for the memory to the active mode, wherein the second rate is greater than the first rate.

These advantage features may be better appreciated by a consideration of the following detailed description.

### BRIEF DESCRIPTION OF THE DRAWINGS

FIG. 1 illustrates an integrated circuit including a memory that is powered according to an aspect of the disclosure.

FIG. 2 is a circuit diagram for the multiplexer in the integrated circuit of FIG. 1 according to an aspect of the disclosure.

FIG. 3 illustrates a logic circuit and a clock for delaying the switching on of the larger transistor during a transition of a memory from a sleep mode to an active mode in accordance with an aspect of the disclosure.

FIG. 4 is a timing diagram for an always-on power supply voltage, a core power supply voltage, and a memory power supply voltage in accordance with an aspect of the disclosure.

FIG. 5 is a flowchart for a method of powering a memory in an integrated circuit in accordance with an aspect of the disclosure.

FIG. 6 illustrates some example electronic systems including an integrated circuit having a memory powered in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

The core, memory, and always-on power supply voltages may each be regulated by a corresponding voltage regulator such as a low-dropout (LDO) voltage regulator. A CX LDO would thus regulate the core memory power supply voltage. Similarly, an AON LDO regulates the always-on power supply voltage whereas an MX LDO regulates the MX power supply voltage. A corresponding power supply voltage rail supports each power supply voltage. The CX power supply voltage is thus carried by a CX power supply voltage rail. In the same fashion, the MX power supply voltage is carried by an MXpower supply voltage rail whereas the AON power supply voltage is carried by an AON power supply voltage rail. The inclusion of three separate voltage regulators occupies the semiconductor die space for the integrated circuit and thus raises manufacturing costs in addition to increasing the power consumption.

To reduce power consumption, increase battery life and decrease the semiconductor die space demands, it is known that the MX power supply voltage rail and the CX power supply voltage rail may be selectively coupled through a multiplexer to a memory input power node for the memory. The input power node voltage and the MX power supply voltage are thus distinct in such an implementation and are only coupled together when the multiplexer selects for the MX supply voltage rail. The MX LDO may regulate the MX power supply voltage to maintain the MX power supply voltage at a greater value than the CX power supply voltage. For example, the MX power supply voltage may equal 0.8V in some implementations whereas the CX power supply voltage may equal 0.4V to 0.7V depending upon the mode of operation for the core power domain. During an active or default mode of operation for the memory, the multiplexer selects for the MX power supply voltage rail so that the memory is powered by the relatively-high value of the MX power supply voltage. But during a retention mode of operation for the memory, the MX LDO may be switched off. With the MX LDO off, the multiplexer selects for the CX power supply voltage rail to couple the CX power supply voltage rail to the memory input power node. In the retention mode, the memory is thus powered by the relatively-lower value of the CX power supply voltage to reduce leakage currents and thus reduce power consumption. Although the memory is dormant in the retention mode, the CX power supply voltage is sufficiently high so that the memory bitcells retain their stored binary contents. Since the MX LDO is disabled during the retention mode, the MX LDO requires some time to increase the MX power supply voltage from ground to its active level during a transition of the memory from the retention mode to the active mode. The resulting transition time for the memory power supply voltage slows the memory operation. To account for this transition period, the sleep mode may be shortened at the cost of increased power consumption.

An integrated circuit or system is provided in which the MX LDO is eliminated to reduce the semiconductor die space demand and reduce power consumption. In addition, the delay from the MX LDO of ramping up the MX power supply voltage from the retention level to the active level is also eliminated. To provide these advantages, a multiplexer is disclosed that selects between the AON power supply voltage rail and the CX power supply voltage rail to couple a selected one of the rails to an MX power supply voltage rail that is directly connected to a power input node for the memory. The AON power supply voltage is greater than the CX core power supply voltage. For example, the AON power supply voltage may equal 0.8V in some implementations whereas the CX power supply voltage may equal 0.4V to 0.7V depending upon the mode of operation for the CX power domain. More generally, the AON power supply voltage is regulated by an AON power supply voltage regulator (e.g., an always-on LDO regulator) to be greater than the CX power supply voltage as regulated by a CX power supply voltage regulator (e.g., a CX LDO). To stabilize the rail voltages, each of the voltage rails may be coupled to an external decoupling capacitor through a corresponding integrated circuit terminal or pin. To protect the integrated circuit from electrostatic shocks, each of the integrated circuit terminals for the voltage rails may be coupled to a corresponding electrostatic discharge (ESD) circuit such as an ESD clamp circuit.

During a transition from the sleep mode to the active mode, the multiplexer selects for the AON power supply voltage rail. But should the MX power supply voltage be increased to the active level too quickly, the corresponding ESD clamp circuit may be undesirably triggered. The multiplexer thus includes at least one first transistor and at least one second transistor coupled in parallel between the AON power supply voltage rail and the MX power supply voltage rail. The second transistor is smaller than the first transistor and thus more resistive. With regard to a transistor size, it may be defined herein as a ratio (W/L) of the transistor channel’s width (W) and length (L). For example, a larger transistor may be formed by two transistors arranged in parallel but having the same width and length. Alternatively, a larger transistor may have a single channel that is either wider or longer (or both) as compared to a smaller transistor. During a transition period while the MX power supply voltage ramps up from ground towards the active level, a controller controls the multiplexer so that only the second transistor is on while the first transistor is maintained off. In this fashion, the voltage increase from the sleep mode to the active mode for the MX power supply voltage is advantageously moderated so that the corresponding ESD clamp circuit is not triggered. After the transition period, the controller may control the multiplexer to switch on both the first and the second transistors so that the MX power supply voltage rail may supply sufficient power to the memory. Similarly, the controller may control the multiplexer to have both the first transistor and the second transistor switched on during a transition of the memory from the retention mode to the active mode because the difference between the active and retention voltage levels is such that a rapid increase from the retention level to the active level does not trigger the ESD clamp circuit coupled to the memory power supply voltage rail.

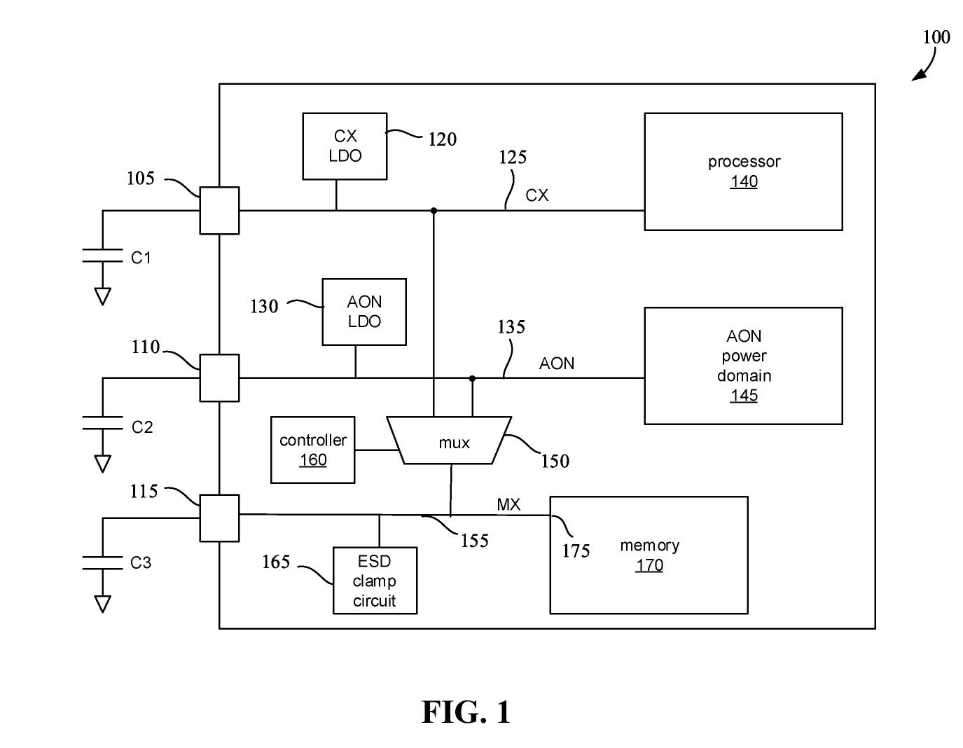

An example integrated circuit 100 or system is shown in FIG. 1. A CX power supply voltage rail 125 that carries the CX power supply voltage memory couples through an integrated circuit terminal 105 to an external decoupling capacitor C1. A CX LDO 120 regulates the CX power supply voltage to power one or more processors 140 in a CX power domain. An AON power supply voltage rail 135 that carries the AON power supply voltage couples through an integrated circuit terminal 110 to an external decoupling capacitor C2. An AON LDO 130 regulates the AON power supply voltage to power an AON power domain 145. As known in the AON arts, the AON power domain 145 includes a power manager that manages the on and off states of the CX and MX power domains.

To power a bitcell array of a memory 170 with an MX power supply voltage from an MX power supply voltage rail 155, a multiplexer 150 as controlled by a controller 160 selects between the CX power supply voltage rail 125 and the AON power supply voltage rail 135. The MX power supply voltage rail 155 couples through an integrated circuit terminal 115 to an external decoupling capacitor C3. The MX power supply voltage rail 155 powers the memory 170 through an input power node 175. The controller 160 controls the multiplexer 150 during a transition of the MX power supply voltage from a cold boot (power-up) or from a sleep mode in which the memory 170 is powered down to the active mode in which the MX power supply voltage increases to an active level equaling the AON power supply voltage. As will be explained further herein, the multiplexer 150 as controlled by the controller 160 moderates the increase of the MX power supply voltage so that the voltage increase does not trigger a clamping by an ESD clamp circuit 165 that protects the integrated circuit 100 from ESD shocks at the terminal 115. To provide this moderation, the multiplexer 150 couples the AON power supply voltage rail 135 to the MX power supply voltage rail 155 through one or more relatively-small transistors as will be explained further herein. But once the transition to the active level is sufficient, the controller 160 switches on one or more relatively-larger transistors in the multiplexer 150 that couple between the AON and MX rails as will also be explained further herein so that the memory 170 is sufficiently powered during the active mode.

During a retention mode for the memory 170, the controller 160 controls the multiplexer 150 to couple the CX power supply voltage rail 125 to the MX power supply voltage rail 155. In this fashion, the MX power supply voltage is reduced to a retention level during the retention mode that equals the CX power supply voltage. The CX power supply voltage is less than the AON power supply voltage but is sufficiently high such that the bitcells in the memory 170 retain their stored binary contents during the retention mode. In a transition from the retention mode to the active mode, the controller 160 may switch on both the relatively-small and the relatively-large transistors simultaneously that couple between the AON power supply voltage rail 125 and the MX power supply voltage rail 155. In this fashion, the MX power supply voltage may quickly transition from the retention level to the active level. Although this transition is faster than the transition from the sleep mode (or cold boot) to the active mode, it does not trigger the ESD clamp circuit 165 because the voltage increase is not as substantial as occurs in a transition from the sleep mode to the active mode.

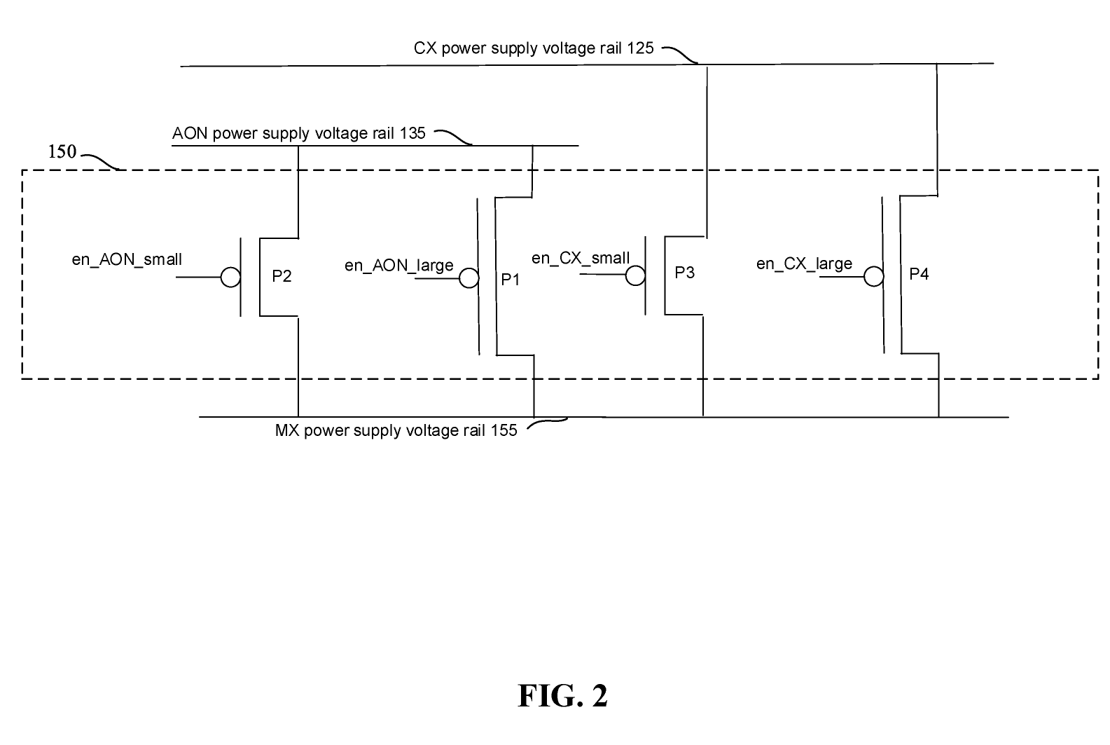

The multiplexer 150 is shown in more detail in FIG. 2. The multiplexer 150 includes at least one first p-type metal-oxide semiconductor (PMOS) transistor P1 and at least one PMOS transistor P2 that couple between the AON power supply voltage rail 135 and the MX power supply voltage rail 155. The first transistor P1 is larger than the transistor P2. An on-resistance of the transistor P2 is thus greater than an on-resistance of the transistor P1. To control whether the transistor P2 is on or off, the controller 160 (FIG. 1) controls whether an enable signal (en_AON_small) that drives a gate of the transistor P2 is grounded (to switch the transistor P2 on) or charged to the AON power supply voltage (to switch the transistor P2 off). Similarly, the controller 160 controls whether an enable signal (en_AON_large) that drives a gate of the transistor P1 is grounded (to switch the transistor P1 on) or charged to the AON power supply voltage (to switch the transistor P1 off).

In a transition from a cold boot or the sleep mode to the active mode for the memory 170 (FIG. 1), the controller 160 first discharges the enable signal en_AON_small while keeping the enable signal en_AON_large charged to switch on only the transistor P2. Since the on-resistance of the transistor P2 is relatively high as compared to the on-resistance of the transistor P1, the ramping up of the MX power supply voltage from ground toward the active level is slowed sufficiently to prevent a triggering of the ESD clamp circuit 165 (FIG. 1). But in a transition from the retention mode to the active mode, the controller 160 may discharge both the enable signals en_AON_large and en_AON_small to switch on the transistors P1 and P2 simultaneously so that the MX power supply voltage transitions relatively quickly from the retention level to the active level. Transistors P1 and P2 are an example of a first means for coupling the always-on power supply voltage rail to the memory power supply voltage rail to cause the memory power supply voltage to increase at a first rate during a transition of the memory from a sleep mode in which the memory is powered down to an active mode in which the memory power supply voltage equals the always-on power supply voltage and to cause the memory power supply voltage to increase at a second rate during a transition of the memory from a retention mode for the memory to the active mode, wherein the second rate is greater than the first rate.

To couple the MX power supply voltage rail 155 to the CX power supply voltage rail 125 during the retention mode, the multiplexer 155 needs at least one transistor that couples between these two rails. To provide an ability to moderate the transition to the retention level for the MX power supply voltage, the multiplexer 155 may includes at least one relatively large transistor (e.g., a PMOS transistor P4) and at least one relatively small transistor (e.g., a PMOS transistor P3) that couple between the CX power supply voltage rail 125 and the MX power supply voltage rail. Transistor P4 may also be denoted herein as a third transistor. Similarly, the transistor P3 may also be denoted herein as a fourth transistor. An enable signal (en_CX_large) drives the gate of the transistor P4 to control the transistor P4 on and off state. Similarly, an enable signal (en_CX_small) drives the gate of the transistor P3 to control the transistor P3 on and off state. Note that in some implementations, the transistor P3 may be eliminated as there may be no need to moderate the ramping of the MX power supply voltage in transitions to the retention state. Transistors P3 and P4 are an example of a second means for coupling the core power supply voltage rail to the memory power supply voltage rail during the retention mode.

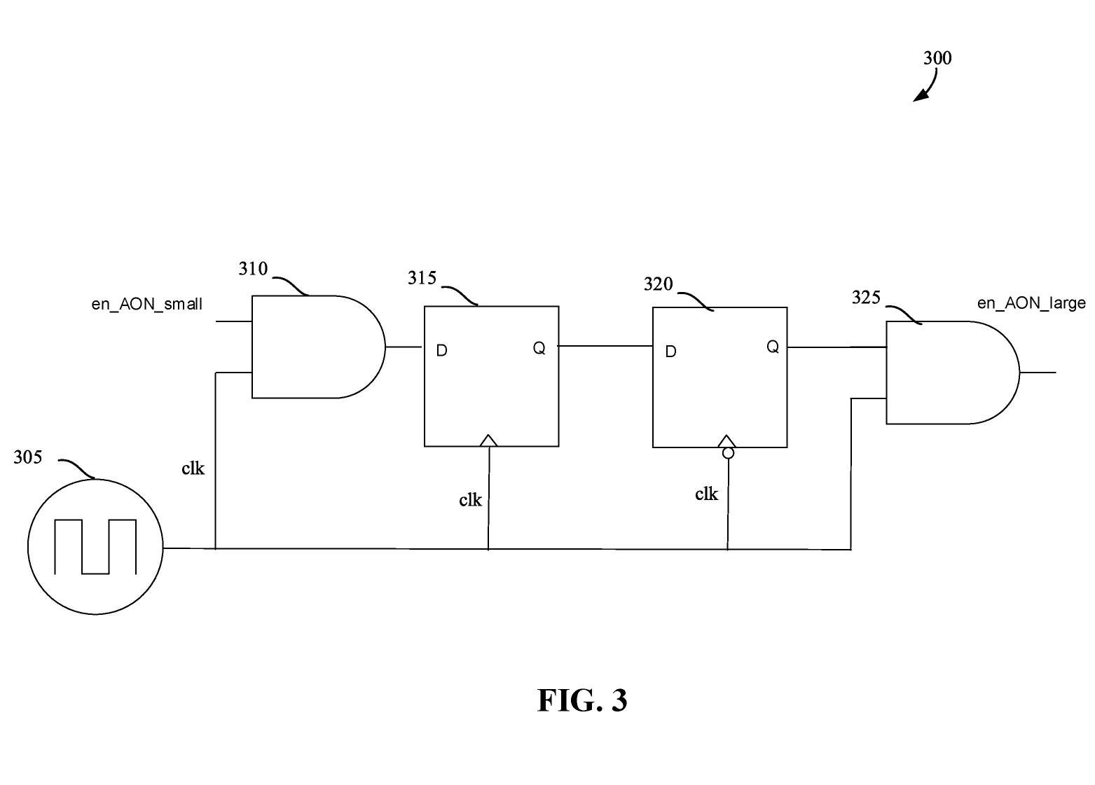

To control the delay between the switching on of the transistor P2 and the transistor P1 as the MX power supply voltage is ramped from ground to the active level, the controller 160 may use a logic circuit 300 as timed from a clock signal (clk) from a clock source 305 as shown in FIG. 3. A logic gate such as an AND gate 310 ANDs the clock signal with the enable signal en_AON_small. An output signal of the AND gate 310 will thus be asserted when the clock signal transitions high during a first clock signal cycle while the enable signal en_AON_small is asserted. A first register 315 registers this output signal responsive to the assertion of the clock signal in the first clock signal cycle. A registered output signal from the register 315 is registered by a second register 320 responsive to the de-assertion of the clock signal during the first clock cycle. A logic gate such as an AND gate 325 that ANDs a registered output signal from the second register 320 with the clock signal to produce the enable signal en_AON_large will thus assert the en_AON_large signal in response to the assertion of the clock signal in a second clock signal cycle following the first clock signal cycle. The clock signal frequency (and thus the clock signal period or cycle length) thus determines the delay between the switching on of the second transistor P2 and the first transistor P1. In some implementations, a 65 KHz clocking frequency for the clock source 305 is suitable but it will be appreciated that slower or faster clock frequencies may be used in alternative implementations. Indeed, a generation of the delay between the assertion of the enable signals may be implemented without using a clock signal in alternative implementations. In some implementations, the transistors P1 and P2 may be replaced by corresponding transmission gates that are sized accordingly. Similarly, the transistors P3 and P4 may be replaced by corresponding transmission gates that are sized accordingly.

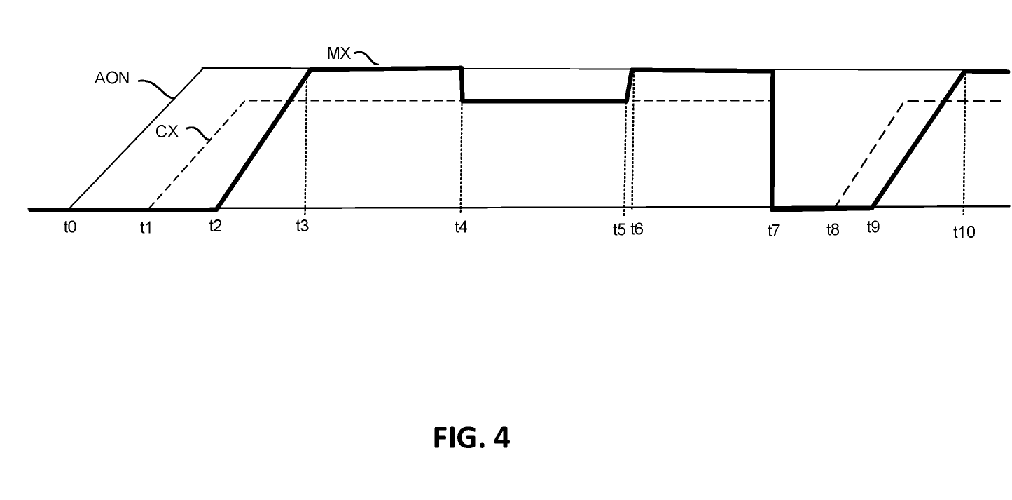

A timing diagram for the AON, CX, and MX power supply voltages is shown in FIG. 4. At time t0, the system begins a cold boot with the AON power supply voltage being ramped up by the AON LDO to its active level. As controlled by the AON power manager, the CX LDO then begins ramping up the CX power supply voltage at a time t1. To transition the memory to the active mode, the MX power supply voltage begins ramping up at a time t2 until it equals the AON power supply voltage at a time t3. During the ramping of the MX power supply voltage at a first rate, only the transistor P2 is on with the transistor P1 being switched on approximately at time t3. At a time t4, the memory transitions to the retention mode through the multiplexer 150 (FIGS. 1 and 2) coupling the CX power supply voltage rail to the MX power supply voltage rail. Transistors P1 and P2 are thus switched off at time t4 whereas transistors P3 and P4 are switched on. At a time t5, the memory again begins a transition to the active mode. Transistors P1 and P2 are both switched on at time t5 with transistors P3 and P4 being switched off. The MX power supply voltage thus increases rapidly at a second rate that is greater than the first rate to equal its active level (equaling the AON power supply voltage) at a time t6. At a time t7, the transistors P1, P2, P3, and P4 are switched off so that the memory may enter the sleep mode in which the MX power supply voltage is discharged to ground. The CX power domain also enters a sleep mode at time t7, but it will be appreciated that the sleep modes for the MX and CX power domains may be operated independently. At a time t8, the CX LDO begins ramping up the CX power supply voltage. Similarly, the MX power supply voltage begins ramping up at the first rate to its active level, which is reached at a time t10.

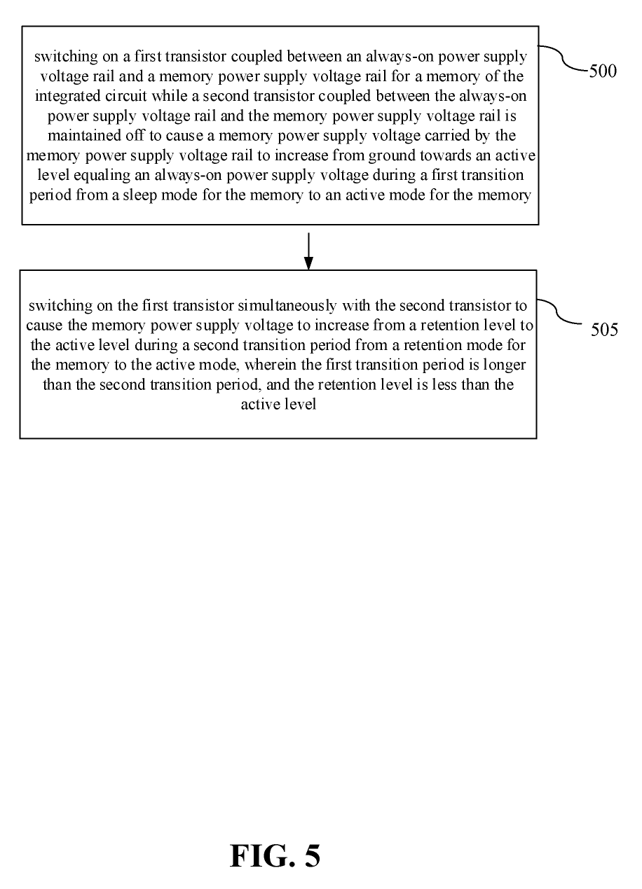

A flowchart for a method of powering an integrated circuit is shown in FIG. 5. The method includes an act 500 of switching on a first transistor coupled between an always-on power supply voltage rail and a memory power supply voltage rail for a memory of the integrated circuit while a second transistor coupled between the always-on power supply voltage rail and the memory power supply voltage rail is maintained off to cause a memory power supply voltage carried by the memory power supply voltage rail to increase from ground towards an active level equaling an always-on power supply voltage during a first transition period from a sleep mode for the memory to an active mode for the memory. The switching on of the transistor P2 in the multiplexer 150 will the transistor P1 is maintained off is an example of act 500. In addition, the period from t2 to t3 in FIG. 4 is an example of the first transition period of act 500. The method further includes an act 505 of switching on the first transistor simultaneously with the second transistor to cause the memory power supply voltage to increase from a retention level to the active level during a second transition period from a retention mode for the memory to the active mode, wherein the first transition period is longer than the second transition period, and the retention level is less than the active level. The switching on of both the transistor P1 and the transistor P2 at time t5 of FIG. 4 is an example of act 505. In addition, the period from time t5 to time t6 is an example of the second transition period of act 505.

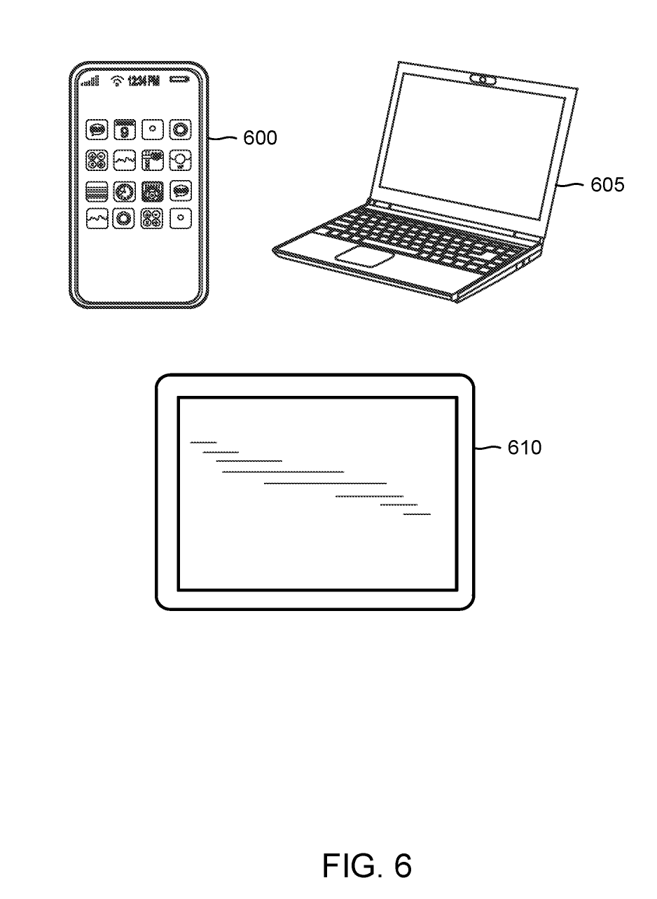

An integrated circuit having a memory powered as disclosed herein may be incorporated into a wide variety of electronic systems. For example, as shown in FIG. 6, a cell phone 600, a laptop 605, and a tablet PC 610 may all include an integrated circuit (or system) including a memory powered as disclosed herein. Other exemplary electronic systems such as a music player, a video player, a communication device, and a personal computer may also be configured with integrated circuits constructed in accordance with the disclosure.

The disclosure will now be summarized in the following example clauses:

Clause 1. An integrated circuit, comprising:

a core power supply voltage regulator configured to regulate a core power supply voltage coupled onto a core power supply voltage rail;

an always-on power supply voltage regulator configured to regulate an always-on power supply voltage coupled onto an always-on power supply voltage rail;

a memory including an input power node to receive an internal power supply voltage; and

a multiplexer including a first transistor and a second transistor coupled in parallel between the always-on power supply voltage rail and the input power node and including at least a third transistor coupled between the core power supply voltage rail and the input power node, wherein the first transistor is larger than the second transistor.

Clause 2. The integrated circuit of clause 1, wherein the multiplexer further includes a fourth transistor coupled in parallel with the third transistor between the core power supply voltage rail and the input power node, wherein the third transistor is larger than the fourth transistor.

Clause 3. The integrated circuit of any of clauses 1-2, further comprising:

a controller configured to switch on the first transistor following an expiration of a delay from a switching on of the second transistor during a transition of the memory from a sleep mode in which the memory is powered down to an active mode in which the memory is powered by the always-on power supply voltage.

Clause 4. The integrated circuit of clause 3, wherein the controller is further configured to time the expiration of the delay responsive to a clock signal.

Clause 5. The integrated circuit of any of clauses 3-4, wherein the controller is further configured to switch on the first transistor and the second transistor simultaneously in a transition of the memory from a retention mode in which the memory is powered by the core power supply voltage to the active mode.

Clause 6. The integrated circuit of any of clauses 3-5, further comprising:

a first terminal coupled to the core power supply voltage rail;

a first capacitor coupled between ground and the first terminal;

a second terminal coupled to the always-on power supply voltage rail; and

a second capacitor coupled between ground and the second terminal.

Clause 7. The integrated circuit of clause 6, further comprising:

a memory power supply voltage rail coupled to the input power node;

a third terminal coupled to the memory power supply voltage rail; and

a third capacitor coupled between ground and the third terminal.

Clause 8. The integrated circuit of any of clauses 1-7, wherein the memory comprises a static random-access memory (SRAM).

Clause 9. The integrated circuit of any of clauses 1-8, wherein the integrated circuit is included within a cellular telephone.

Clause 10. The integrated circuit of clause 7, further comprising:

an electrostatic discharge clamp circuit coupled to the third terminal, wherein the delay is sufficient to prevent a triggering of the electrostatic discharge clamp circuit.

Clause 11. The integrated circuit of clause 3, wherein the controller is further configured to switch on the first transistor following an expiration of the delay from a switching on of the second transistor during a cold bootup of the integrated circuit.

Clause 12. A method of powering an integrated circuit, comprising:

switching on a first transistor coupled between an always-on power supply voltage rail and a memory power supply voltage rail for a memory of the integrated circuit while a second transistor coupled between the always-on power supply voltage rail and the memory power supply voltage rail is maintained off to cause a memory power supply voltage carried by the memory power supply voltage rail to increase from ground towards an active level equaling an always-on power supply voltage during a first transition period from a sleep mode for the memory to an active mode for the memory; and

switching on the first transistor simultaneously with the second transistor to cause the memory power supply voltage to increase from a retention level to the active level during a second transition period from a retention mode for the memory to the active mode, wherein the first transition period is longer than the second transition period, and the retention level is less than the active level.

Clause 13. The method of clause 12, further comprising:

switching off both the first transistor and the second transistor during a transition of the memory into the retention mode while switching on a third transistor to couple the memory power supply voltage rail to a core power supply voltage rail to cause the memory power supply voltage to decrease from the active level to the retention level.

Clause 14. The method of any of clauses 12-13, wherein the increase from ground towards the active level during the first transition period occurs at a rate that does not trigger an electrostatic discharge clamp circuit coupled to the memory power supply voltage rail.

Clause 15. A system, comprising:

a memory power supply voltage rail;

a memory configured to be powered by a memory power supply voltage from the memory power supply voltage rail;

an always-on power supply voltage rail;

an always-on power domain configured to be powered by an always-on power supply voltage from the always-on power supply voltage rail; and

first means for coupling the always-on power supply voltage rail to the memory power supply voltage rail to cause the memory power supply voltage to increase at a first rate during a transition of the memory from a sleep mode in which the memory is powered down to an active mode in which the memory power supply voltage equals the always-on power supply voltage and to cause the memory power supply voltage to increase at a second rate during a transition of the memory from a retention mode for the memory to the active mode, wherein the second rate is greater than the first rate.

Clause 16. The system of clause 15, further comprising:

a core power supply voltage rail;

a core power domain configured to be powered by a core power supply voltage from the core power supply voltage rail; and

second means for coupling the core power supply voltage rail to the memory power supply voltage rail during the retention mode.

Clause 17. The system of clause 16, further comprising:

a first voltage regulator configured to regulate the core power supply voltage; and

a second voltage regulator configured to regulate the always-on power supply voltage.

Clause 18. The system of clause 17, wherein the first voltage regulator and the second voltage regulator each comprises a low drop-out (LDO) voltage regulator.

Clause 19. The system of any of clauses 17-18, further comprising:

a first terminal coupled to the core power supply voltage rail;

a first capacitor coupled between ground and the first terminal;

a second terminal coupled to the always-on power supply voltage rail;

a second capacitor coupled between ground and the second terminal.

a third terminal coupled to the memory power supply voltage rail; and

a third capacitor coupled between ground the third terminal.

Clause 20. The system of clause 19, further comprising:

As those of some skill in this art will by now appreciate and depending on the particular application at hand, many modifications, substitutions and variations can be made in and to the materials, apparatus, configurations and methods of use of the devices of the present disclosure without departing from the scope thereof. In light of this, the scope of the present disclosure should not be limited to that of the particular implementations illustrated and described herein, as they are merely by way of some examples thereof, but rather, should be fully commensurate with that of the claims appended hereafter and their functional equivalents.

We claim:

1. An integrated circuit, comprising:
a core power supply voltage regulator configured to regulate a core power supply voltage coupled onto a core power supply voltage rail;
an always-on power supply voltage regulator configured to regulate an always-on power supply voltage coupled onto an always-on power supply voltage rail;
a memory including an input power node to receive an internal power supply voltage; and
a multiplexer including a first transistor and a second transistor coupled in parallel between the always-on power supply voltage rail and the input power node and including at least a third transistor coupled between the core power supply voltage rail and the input power node, wherein the first transistor is larger than the second transistor.

2. The integrated circuit of claim 1, wherein the multiplexer further includes a fourth transistor coupled in parallel with the third transistor between the core power supply voltage rail and the input power node, wherein the third transistor is larger than the fourth transistor.

3. The integrated circuit of claim 1, further comprising:
a controller configured to switch on the first transistor following an expiration of a delay from a switching on of the second transistor during a transition of the memory from a sleep mode in which the memory is powered down to an active mode in which the memory is powered by the always-on power supply voltage.

4. The integrated circuit of claim 3, wherein the controller is further configured to time the expiration of the delay responsive to a clock signal.

5. The integrated circuit of claim 3, wherein the controller is further configured to switch on the first transistor and the second transistor simultaneously in a transition of the memory from a retention mode in which the memory is powered by the core power supply voltage to the active mode.

6. The integrated circuit of claim 3, further comprising:
a first terminal coupled to the core power supply voltage rail;
a first capacitor coupled between ground and the first terminal;
a second terminal coupled to the always-on power supply voltage rail; and
a second capacitor coupled between ground and the second terminal.

7. The integrated circuit of claim 6, further comprising:
a memory power supply voltage rail coupled to the input power node;
a third terminal coupled to the memory power supply voltage rail; and
a third capacitor coupled between ground and the third terminal.

8. The integrated circuit of claim 1, wherein the memory comprises a static random-access memory (SRAM).

9. The integrated circuit of claim 8, wherein the integrated circuit is included within a cellular telephone.

10. The integrated circuit of claim 7, further comprising:
an electrostatic discharge clamp circuit coupled to the third terminal, wherein the delay is sufficient to prevent a triggering of the electrostatic discharge clamp circuit.

11. The integrated circuit of claim 3, wherein the controller is further configured to switch on the first transistor following an expiration of the delay from a switching on of the second transistor during a cold bootup of the integrated circuit.

12. A method of powering an integrated circuit, comprising:
switching on a first transistor coupled between an always-on power supply voltage rail and a memory power supply voltage rail for a memory of the integrated circuit while a second transistor coupled between the always-on power supply voltage rail and the memory power supply voltage rail is maintained off to cause a memory power supply voltage carried by the memory power supply voltage rail to increase from ground towards an active level equaling an always-on power supply voltage during a first transition period from a sleep mode for the memory to an active mode for the memory; and
switching on the first transistor simultaneously with the second transistor to cause the memory power supply voltage to increase from a retention level to the active level during a second transition period from a retention mode for the memory to the active mode, wherein the first transition period is longer than the second transition period, and the retention level is less than the active level.

13. The method of claim 12, further comprising:
switching off both the first transistor and the second transistor during a transition of the memory into the retention mode while switching on a third transistor to couple the memory power supply voltage rail to a core power supply voltage rail to cause the memory power supply voltage to decrease from the active level to the retention level.

14. The method of claim 12, wherein the increase from ground towards the active level during the first transition period occurs at a rate that does not trigger an electrostatic discharge clamp circuit coupled to the memory power supply voltage rail.

15. A system, comprising:
a memory power supply voltage rail;
a memory configured to be powered by a memory power supply voltage from the memory power supply voltage rail;
an always-on power supply voltage rail;
an always-on power domain configured to be powered by an always-on power supply voltage from the always-on power supply voltage rail; and
first means for coupling the always-on power supply voltage rail to the memory power supply voltage rail to cause the memory power supply voltage to increase at a first rate during a transition of the memory from a sleep mode in which the memory is powered down to an active mode in which the memory power supply voltage equals the always-on power supply voltage and to cause the memory power supply voltage to increase at a second rate during a transition of the memory from a retention mode for the memory to the active mode, wherein the second rate is greater than the first rate.

16. The system of claim 15, further comprising:
a core power supply voltage rail;
a core power domain configured to be powered by a core power supply voltage from the core power supply voltage rail; and
second means for coupling the core power supply voltage rail to the memory power supply voltage rail during the retention mode.

17. The system of claim 16, further comprising:
a first voltage regulator configured to regulate the core power supply voltage; and
a second voltage regulator configured to regulate the always-on power supply voltage.

18. The system of claim 17, wherein the first voltage regulator and the second voltage regulator each comprises a low drop-out (LDO) voltage regulator.

19. The system of claim 17, further comprising:
a first terminal coupled to the core power supply voltage rail;
a first capacitor coupled between ground and the first terminal;
a second terminal coupled to the always-on power supply voltage rail;
a second capacitor coupled between ground and the second terminal.
a third terminal coupled to the memory power supply voltage rail; and
a third capacitor coupled between ground the third terminal.

20. The system of claim 19, further comprising:
an electrostatic discharge clamp circuit coupled to the third terminal, wherein the first rate is sufficiently slow to prevent a triggering of the electrostatic discharge clamp circuit.
